(19) United States
(12) Patent Application Publication
(10) Pub. No.: US 2021/0242269 A1
(43) Pub. Date: Aug. 5, 2021

(54) IMAGE SENSOR PACKAGE

(71) Applicant: CANON KABUSHIKI KAISHA, Tokyo (JP)

(72) Inventor: Daisuke Toda, Kanagawa (JP)

(21) Appl. No.: 17/165,654

(22) Filed: Feb. 2, 2021

(30) Foreign Application Priority Data
Feb. 5, 2020 (JP) 2020-018130

(51) Int. Cl. H01L 27/146; H05K 1/11

(52) U.S. Cl. CPC H01L 27/14636; H05K 2201/10151; H05K 2201/10204; H05K 1/11

(57) ABSTRACT

An image sensor package includes an image sensor, a printed circuit board having a plurality of conductor layers, and a resin molded portion provided so as to surround an outer circumference of the printed circuit board. A first conductor layer among the plurality of conductor layers, which is closest to the resin molded portion has a dummy pattern formed along a circumference inside the resin molded portion.

### BACKGROUND OF THE INVENTION

### Field of the Invention

The present invention relates to an image sensor package.

### Description of the Related Art

A so-called packageless structure has conventionally been known in which an image sensor is directly mounted on a printed circuit board made of glass epoxy or the like. Japanese Patent Laid-Open No. (“JP”) 2015-185763 discloses an image sensor package that includes a printed circuit board, and a resin molded portion surrounding an outer circumference of the printed circuit board. PCT International Publication No. (“WO”) 2009/150820 discloses a resin molding method for preventing a printed circuit board from getting damaged by roundly chamfering a contact surface of a mold with the printed circuit board and by providing a recess in the printed circuit board.

The image sensor package disclosed in JP 2015-185763 clamps the printed circuit board by the mold when the printed circuit board is inserted into the mold. Therefore, the printed circuit board may be cracked at the contact surface with the mold, or internal wirings of the printed circuit board may be deformed or broken. In the method disclosed in WO 2009/150820, when the thickness of the printed circuit board varies, the pressure applied to the printed circuit board increases in the entire contact area between the mold and the printed circuit board, and a conductor layer placed directly under the contact area and the resin material of the printed circuit board are likely to get damaged.

### SUMMARY OF THE INVENTION

The present invention provides an image sensor package which can form a resin molded portion on the outer circumference of a printed circuit board without being electrically defective even if the printed circuit board gets damaged.

An image sensor package according to one aspect of the present invention includes an image sensor, a printed circuit board having a plurality of conductor layers, and a resin molded portion provided so as to surround an outer circumference of the printed circuit board. A first conductor layer among the plurality of conductor layers, which is closest to the resin molded portion has a dummy pattern formed along a circumference inside the resin molded portion.

Further features of the present invention will become apparent from the following description of exemplary embodiments with reference to the attached drawings.

### BRIEF DESCRIPTION OF THE DRAWINGS

FIGS. 1A and 1B illustrate a structure of a printed circuit board in a first embodiment.

FIGS. 2A and 2B illustrate a structure of a mold in the first embodiment.

FIGS. 3A to 3E explain a printed circuit board inserted into the mold in the first embodiment.

FIG. 4A to 4F illustrate a structure of an image sensor package according to the first embodiment.

FIGS. 5A to 5G illustrate the structure of the image sensor package according to the first embodiment.

FIGS. 6A to 6C explain a method for manufacturing the image sensor package according to the first embodiment.

FIGS. 7A to 7E illustrate a structure of an image sensor package according to a second embodiment.

FIGS. 8A to 8E illustrate a structure of an image sensor package according to a third embodiment.

FIGS. 9A to 9C illustrate a structure of an image sensor package according to Comparative Example 1.

FIGS. 10A to 10E explain a printed circuit board inserted into a mold according to Comparative Example 2.

FIGS. 11A to 11F illustrate a structure of an image sensor package according to Comparative Example 2.

FIGS. 12A to 12C illustrate the structure of the image sensor package according to Comparative Example 2.

### DESCRIPTION OF THE EMBODIMENTS

Referring now to the accompanying drawings, a detailed description will be given of embodiments according to the present invention.

### First Embodiment

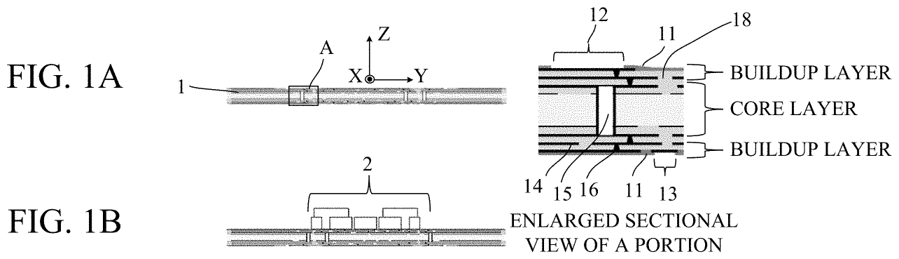

Referring now to FIGS. 1A to 1B, a description will be given of an image sensor package according to a first embodiment of the present invention. FIGS. 1A and 1B are structural diagrams (sectional views) of a printed circuit board in the image sensor package, and illustrate a process sequence of manufacturing the image sensor package.

FIG. 1A illustrates a stage in which the printed circuit board 1 is prepared, and is a sectional view of a printed circuit board 1 in a coordinate system XYZ illustrated in the figure. The printed circuit board 1 may be a plate-shaped substrate including a circuit conductor, which is suitable because it can easily use for a circuit conductor, for example, a rigid substrate such as a silicon substrate or a ceramic substrate, or a copper foil whose resin substrate has a low electrical resistance. FIG. 1A illustrates an example in which the resin substrate is used as the printed circuit board 1.

On the right side of FIG. 1A, a detailed layer structure of the printed circuit board 1 is illustrated as an enlarged sectional view of part A. The printed circuit board 1 is an illustrative so-called 2-4-2 buildup substrate that includes a core layer including a plurality of conductor layers 14 (four copper foil layers) and conductor layers 14 as buildup layers provided two layers each on the front and back surfaces of the core layer. Each of the plurality of conductor layers 14 is desirably patterned by lithography. Each of the core layer and the buildup layers may include a prepreg layer 18. The prepreg layer 18 is formed by weaving or knitting fiber on a cloth and impregnating the resin into the cloth. The main components of the resin are, for example, epoxy and phenol. The resin also contains an insulating filler such as paper and glass. The fiber is, for example, glass fiber, but is not limited to this example as long as it is insulative.

Solder resist layers 11 are provided on the front and back surfaces of the printed circuit board 1. The solder resist layer 11 is formed by laminating a dry film on each of the front and back surfaces of the printed circuit board 1 and then by patterning each surface by lithography to provide openings at desired locations. However, the present invention is not limited to this process, and another method is applicable, such as a method of applying the liquid resist using a roll coater or a spray coater, of UV or thermally curing it, and then of patterning it in the same manner. A front surface electrode 12 is an electrode for connecting the wiring from the image sensor. A back surface electrode 13 is an electrode for connecting electronic components. The front surface electrode 12 and the back surface electrode 13 are conducted in desired paths via a conductor layer 14, a laser via 16, and a drill via 15.

FIG. 1B illustrates a process of mounting an electronic component 2 on the back surface of the printed circuit board 1. The electronic component 2 is soldered onto the back surface of the printed circuit board 1 by a known surface mounting method. More specifically, first, a printing mask having openings that match the arrangement of the provided back surface electrodes 13 is prepared while the back surface of the printed circuit board 1 is set to a top surface. Next, the printing mask is brought into contact with the back surface so that the opening thereof and the back surface electrode 13 are aligned with each other. In that state, the solder paste is placed on the mask, and the solder paste is printed on the back surface of the printed circuit board 1 using a squeegee. Next, using a known mounter, desired components are mounted on the back surface of the printed circuit board 1 so that the back surface electrode 13 and the terminal of each electronic component correspond to each other. Finally, it is passed through a reflow furnace in that state to complete the solder bonding between the back surface electrode 13 and the terminal of each electronic component.

If the flux contained in the solder paste is separated from the printed circuit board 1 in the subsequent process and adhered to the image sensor, it causes the yield to decrease. Therefore, it is desirable to clean the flux using a known cleaning machine and a known cleaning solution. The electronic component can suitably use one for surface mounting. The electronic component includes, for example, a ceramic capacitor, an organic capacitor, such as tantalum, a chip resistor, a B to B connector, a power supplying regulator IC, a common mode filter coil, a temperature measurement IC, EPROMs, etc., but is not limited to them.

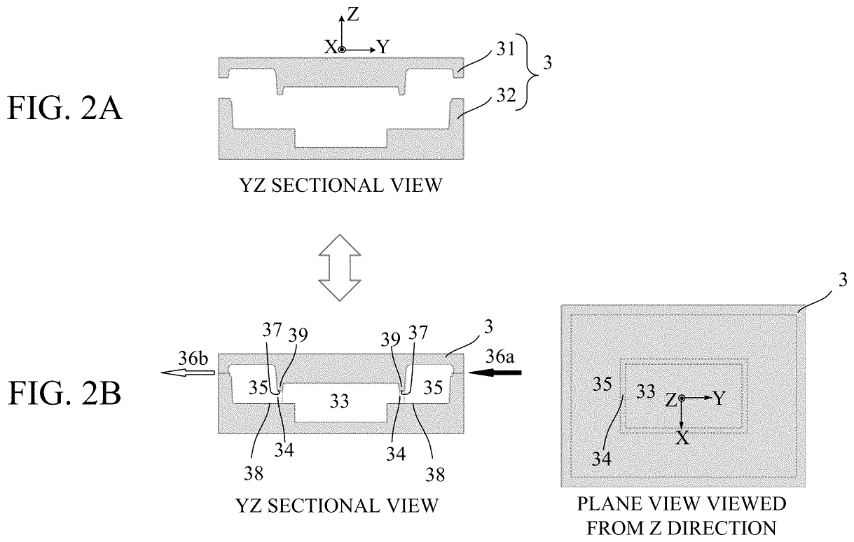

Referring now to FIGS. 2A and 2B, a description will be given of a mold 3 according to this embodiment. FIGS. 2A and 2B are structural views of the mold 3. FIG. 2A illustrates a sectional view of the mold 3 in an open state, and FIG. 2B illustrates a sectional view of the mold 3 in a closed state and a plan view viewed from the Z direction. As illustrated in FIG. 2A, the coordinate system XYZ is used for the mold 3 as in FIG. 1A. The mold 3 has an upper mold 31 and a lower mold 32. As illustrated in the sectional view of FIG. 2B, a cavity is formed inside the mold 3 in a state where the mold 3 is closed. The plan view viewed from the Z direction in FIG. 2B is a view of the mold 3 viewed from the Z direction of the coordinate system illustrated in FIG. 2A, and a broken line in the figure shows boundary lines that divide a cavity formed inside the mold 3 into three parts. As illustrated in FIG. 2B, the cavity includes a central cavity 33, a frame-shaped narrow cavity 34 provided in the outer circumference of the central cavity 33, and a frame-shaped cavity 35 provided in the outer circumference of the frame-shaped narrow cavity 34.

A gate (not shown) for injecting the resin in a direction indicated by an arrow 36a in FIG. 2B and an air vent (not shown) for removing air expelled by the resin in a direction indicated by an arrow 36b are provided in the mold 3. A frame-shaped convex portion 39 is formed in the cavity of the mold 3. A top frame-shaped plane 37 of the frame-shaped convex portion 39 and an opposite plane 38 provided opposite to the top frame-shaped plane 37 sandwich the printed circuit board 1.

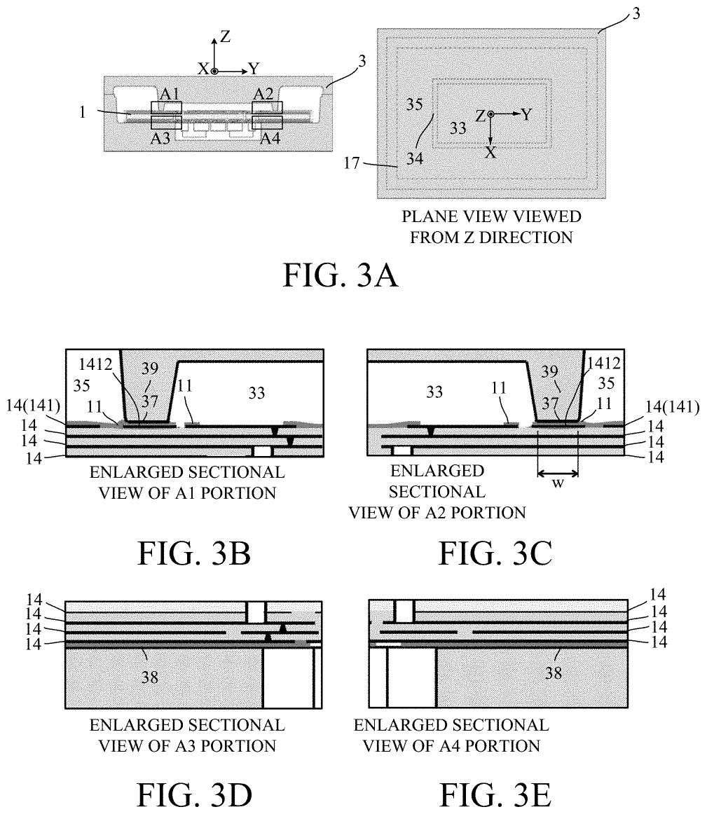

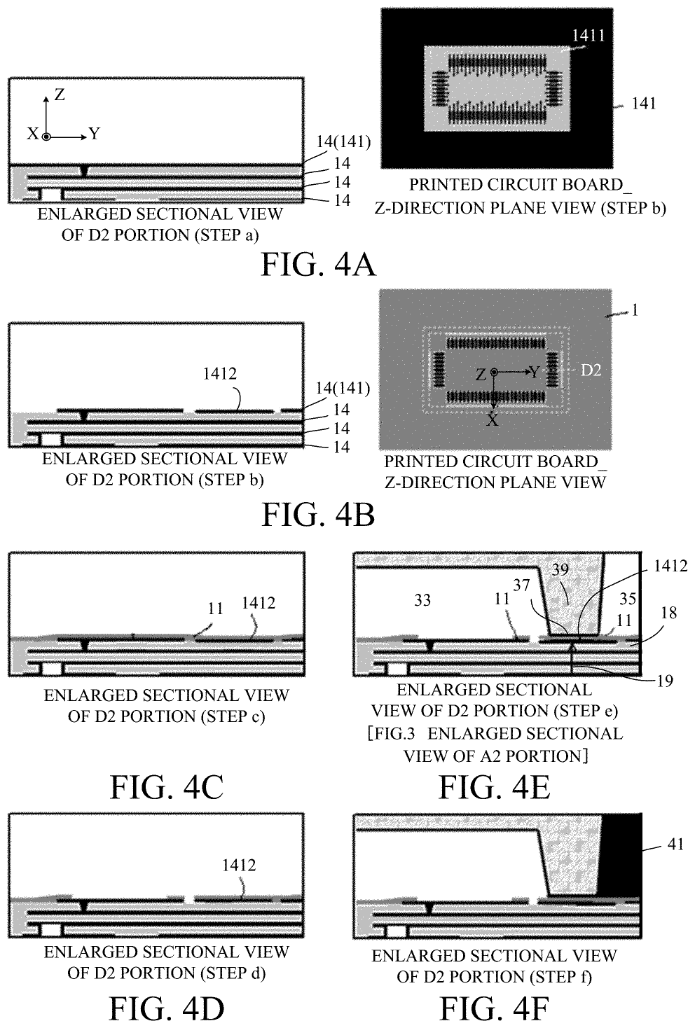

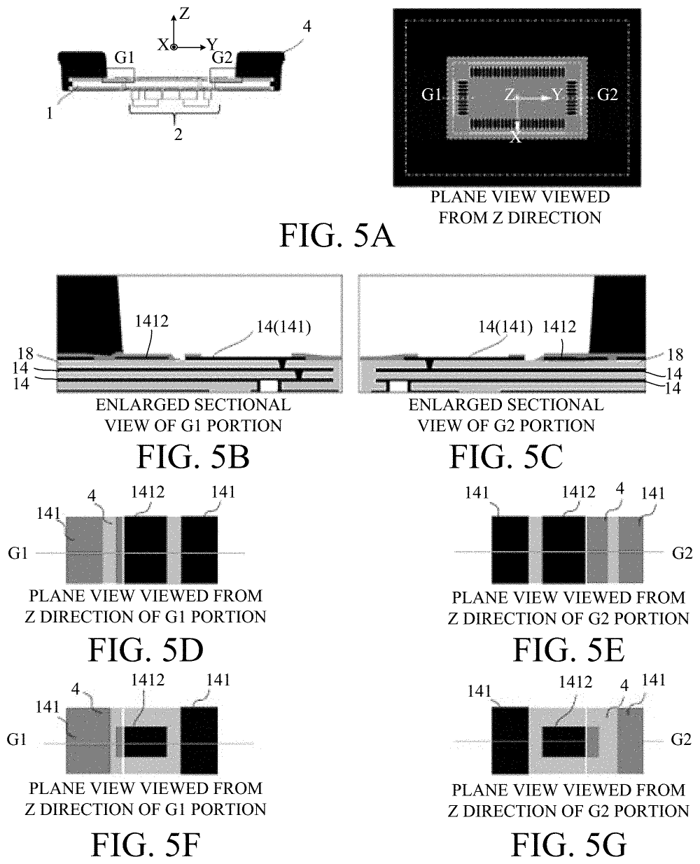

Referring now to FIGS. 3A to 3E and 4A to 4F, a description will be given of a method of manufacturing the printed circuit board 1. FIG. 3A to 3E explain the printed circuit board 1 inserted into the mold 3. FIGS. 4A to 4F and 5A to 5G explain the image sensor package. The sectional views of FIGS. 4A to 4F are enlarged views of the section corresponding to a line D2 illustrated in the plan view viewed from the Z direction of the printed circuit board in FIG. 4B (“printed circuit board_Z-direction plan view”).

The printed circuit board 1 is a so-called 2-4-2 buildup board, and the step “a” illustrated in FIG. 4A is a step of forming build-up layers two each on both sides of the core layer. The step “b” illustrated in FIG. 4B illustrates the uppermost conductor layer 141 formed in the step “a” is patterned by lithography. A conductor layer 141 is a conductor layer closest to the top frame-shaped plane 37 (in other words, a conductor layer closest to the resin molded portion 4) while the printed circuit board 1 is inserted into the mold 3 illustrated in FIGS. 3A to 3E. The printed circuit board_Z direction plan view (step “b”) in FIG. 4A is a plan view of the printed circuit board 1 viewed from the Z direction in step “b.” The conductor layer 141 has an underframe conductor layer 1412 as a dummy pattern in a portion sandwiched by two square-shaped broken lines.

Similarly, the underframe conductor layer 1412 is illustrated in the enlarged sectional view of the D2 portion (step “b”) in FIG. 4B. As can be seen by comparing FIG. 4B with the enlarged sectional view of the A2 portion of FIG. 3C, the underframe conductor layer 1412 is a portion where the top frame-shaped plane 37 of the mold 3 and the conductor layer 141 are opposite to each other. The underframe conductor layer 1412 is provided to that portion, and the top frame-shaped plane 37 and the underframe conductor layer 1412 are arranged so as to overlap each other at least partially in the plane direction. The underframe conductor layer 1412 is provided as a dummy pattern that is separated from the peripheral pattern and is not electrically connected. The underframe conductor layer 1412 in the plan view viewed from the Z direction has a rectangular shape or a partially disposed shape made by dividing the rectangular shape at one or more locations.

The step “c” illustrated in FIG. 4C is the step of forming the solder resist layer 11. The solder resist layer 11 is formed by applying heat or UV to a liquid resist applied using a known roll coater, spin coater, spray coater, or the like, and by solidifying the liquid resist. The step “d” illustrated in FIG. 4D is the step of exposing and developing the cured solder resist layer 11 to provide an opening in a desired portion and finish the printed circuit board 1. FIG. 4E illustrates the printed circuit board 1 inserted into the mold 3 and sandwiched between the top frame-shaped plane 37 and the opposite plane 38, and corresponds to the same view as the enlarged sectional view of the A2 portion of FIG. 3C. In this state, the frame-shaped convex portion 39 may enter the solder resist layer 11, and the solder resist layer 11 and the underframe conductor layer 1412 may be deformed. In that case, the prepreg layer 18 also has a slight dent at the portion indicated by an arrow 19 in FIG. 4E.

In this embodiment, the underframe conductor layer 1412 is provided as a dummy pattern that is separated from the peripheral pattern and is not electrically connected. Therefore, even if the underframe conductor layer 1412 is deformed to cause damages such as cracks or disconnections, the underframe conductor layer 1412 is the electrical dummy pattern, so that no electrical changes occurs. Since the underframe conductor layer 1412 has a predetermined thickness, the dent of the lower prepreg layer 18 can be reduced. Thereby, the image sensor package can avoid electrical defects or the printed circuit board 1 can avoid cracks.

The step “f” illustrated in FIG. 4F is the step of pouring resin 41 into the frame-shaped cavity 35 that is part of the cavity in the mold 3. The sectional view on the left side in FIG. 5A illustrates the finished image sensor package (having no image sensor). The image sensor package includes a printed circuit board 1 having a plurality of conductor layers 14 and a resin molded portion (frame-shaped resin molded portion) 4 provided so as to surround the outer circumference of the printed circuit board 1.

In this embodiment, a first conductor layer (conductor layer 141) closest to the resin molded portion 4 among the plurality of conductor layers 14 is a dummy pattern (underframe conductor layer 1412) formed along the circumference inside the resin molded portion 4. The underframe conductor layer 1412 is not electrically connected to another pattern of the first conductor layer (another conductor of the conductor layer 141 other than the underframe conductor layer 1412). The underframe conductor layer 1412 is formed on an entire circumference or part of the circumference inside the resin molded portion 4.

In this embodiment, at least part of the underframe conductor layer 1412 is covered with the solder resist layer 11 obtained by curing the liquid resist, but the solder resist layer 11 may not exist on the underframe conductor layer 1412. As described above, in the image sensor package illustrated in FIG. 5A, the underframe conductor layer 1412 is deformed, and the prepreg layer 18 illustrated in FIG. 4E also has a slight dent at the portion indicated by the arrow 19. However, according to the structure according to this embodiment, the image sensor package is not electrically defective, and the printed circuit board 1 has no cracks.

FIGS. 5D and 5E are plan views viewed from the Z direction of G1 and G2 portions (see FIGS. 5A to 5C) showing an illustrative shape of the underframe conductor layer 1412, when the underframe conductor layer 1412 has a rectangular pattern provided on the entire circumference along the inside of the resin molded portion 4. The underframe conductor layer 1412 is a rectangular dummy pattern that is separated from the peripheral pattern and is not electrically connected. FIGS. 5F and 5G are plan views viewed from the Z direction of the G1 and G2 portions showing another illustrative shape of the underframe conductor layer 1412, when the underframe conductor layer 1412 has a rectangular pattern partially provided along the inside of the resin molded portion 4. The underframe conductor layer 1412 is partially disposed as a dummy pattern that is not electrically connected and is separated from the peripheral pattern.

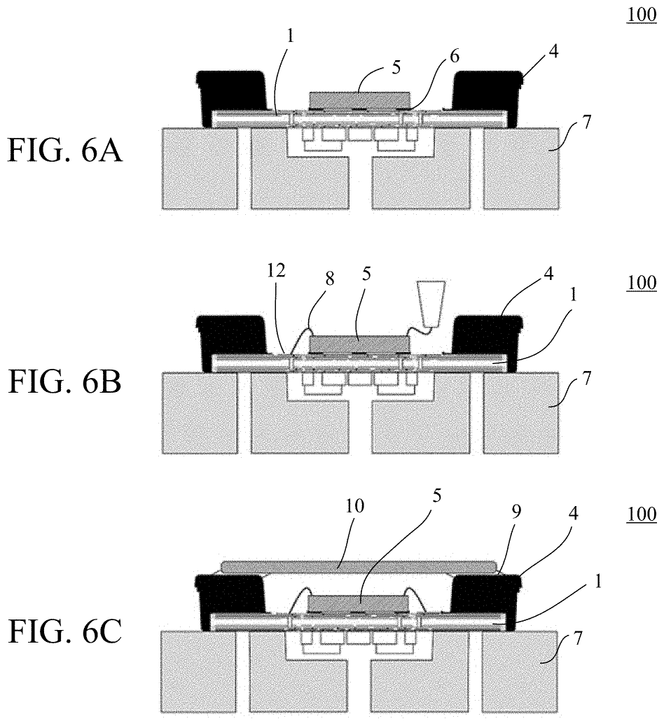

Referring now to FIGS. 6A to 6C, a description will be given of a method of manufacturing the image sensor package 100 (mounted with the image sensor) according to this embodiment. FIGS. 6A to 6C explain a manufacturing method of the image sensor package 100. First, as illustrated in FIG. 6A, the image sensor package 100 having the printed circuit board 1 and the resin molded portion 4 is fixed onto a known attraction stage 7. Then, the image sensor 5 which is a semiconductor chip is adhered to the central portion of the image sensor package 100 via a known adhesive 6. Next, as illustrated in FIG. 6B, an electrode pad of the image sensor 5 and a front surface electrode 12 of the image sensor package 100 are connected to each other by a known wire bonding method using a known wire 8. Finally, as illustrated in FIG. 6C, the image sensor package 100 is finished by adhering a known light-transmissive LID 10 to the resin molded portion 4 via a known adhesive 9.

### Second Embodiment

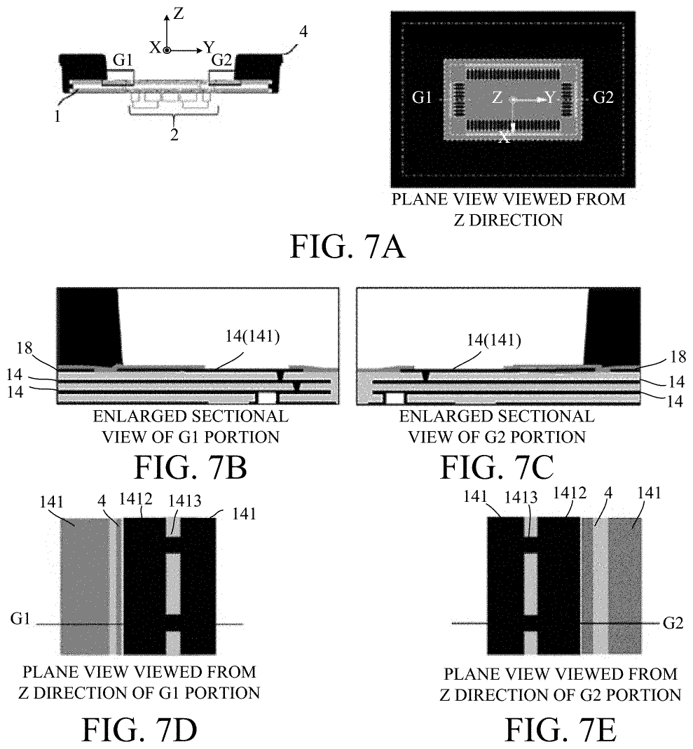

Referring now to FIGS. 7A to 7E, a description will be given of an image sensor package according to a second embodiment of the present invention. FIGS. 7A to 7E explain the image sensor package according to this embodiment. FIGS. 7A to 7E correspond to FIGS. 5A to 5E described in the first embodiment, and illustrate the finished image sensor package (having no image sensor) according to this embodiment. Since the method of manufacturing the image sensor package in this embodiment is the same as that in the first embodiment, a description thereof will be omitted.

The image sensor package according to this embodiment includes a printed circuit board 1 having a plurality of conductor layers 14, and a resin molded portion 4 provided so as to surround the outer circumference of the printed circuit board 1. A conductor layer 141 among the plurality of conductor layers 14 which is closest to the resin molded portion 4 has an underframe conductor layer 1412 in the entire circumference or part of the circumference along the inside of the resin molded portion 4. The underframe conductor layer 1412 is disposed as a pattern partially connected to the peripheral pattern. The underframe conductor layer 1412 has a rectangular shape or a partially disposed shape made by dividing the rectangular shape at one or more locations. In this embodiment, at least part of the underframe conductor layer 1412 is covered with the solder resist layer 11 obtained by curing the liquid resist, but the solder resist layer 11 may not exist on the underframe conductor layer 1412.

FIGS. 7D and 7E are plan views viewed from the Z direction of G1 and G2 portions (see FIGS. 7A to 7C) showing an illustrative shape of the underframe conductor layer 1412, when the underframe conductor layer 1412 has a rectangular pattern provided on the entire circumference along the inside of the resin molded portion 4 and partially connected to the conductor layer 141 inside the underframe conductor layer 1412 via a connector 1413. In other words, the conductor layer 141 has the connector 1413 that electrically connects with each other part of the underframe conductor layer 1412 and part of the pattern inside the underframe conductor layer 1412 among other patterns in the conductor layer 141.

As described above, in the image sensor package structured as illustrated in FIGS. 7A to 7E, the underframe conductor layer 1412 is deformed, and the prepreg layer 18 also has a slight dent at the portion indicated by the arrow 19. In this embodiment, the underframe conductor layer 1412 is provided as a pattern that is partially connected through the connector 1413 to the conductor layer 141 inside the underframe conductor layer 1412. Therefore, the underframe conductor layer 1412 may be deformed and cause cracks in the connector 1413, and it may be damaged and separated from the peripheral pattern. When the damage such as a crack and a disconnection occurs in the connector 1413, the underframe conductor layer 1412 is electrically structured as a dummy pattern, which does not electrically vary. In addition, the underframe conductor layer 1412 having a predetermined thickness can reduce the dent in the prepreg layer 18 in the lower layer.

In this embodiment, when the underframe conductor layer 1412 is separated from the peripheral pattern, the structure is the same as that of the first embodiment, and the underframe conductor layer 1412 has a dummy pattern, which does not electrically vary. As a result, the image sensor package does not become electrically defective and the printed circuit board 1 does not contain any cracks.

### Third Embodiment

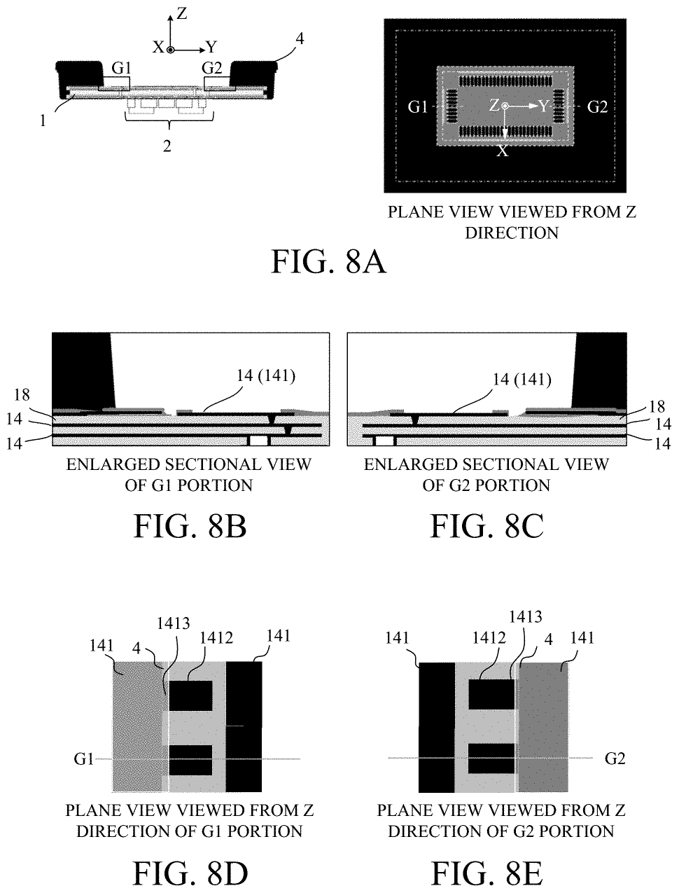

Referring now to FIGS. 8A to 8E, a description will be given of an image sensor package according to a third embodiment of the present invention. FIGS. 8A to 8E explain the image sensor package in this embodiment. FIGS. 8A to 8E correspond to FIGS. 5A to 5E described in the first embodiment, and illustrate the finished image sensor package (having no image sensor) according to this embodiment. Since the method of manufacturing the image sensor package in this embodiment is the same as that in the first embodiment, a description thereof will be omitted.

The image sensor package according to this embodiment includes a printed circuit board 1 having a plurality of conductor layers 14, and a resin molded portion 4 provided so as to surround the outer circumference of the printed circuit board 1. A conductor layer 141 among the plurality of conductor layers 14 which is closest to the resin molded portion 4 has an underframe conductor layer 1412 in the entire circumference or part of the circumference along the inside of the resin molded portion 4. The underframe conductor layer 1412 is disposed as a pattern partially connected to the peripheral pattern. The underframe conductor layer 1412 has a partially disposed shape made by dividing the rectangular shape at one or more locations. In this embodiment, at least part of the underframe conductor layer 1412 is covered with the solder resist layer 11 obtained by curing the liquid resist, but the solder resist layer 11 may not exist on the underframe conductor layer 1412.

FIGS. 8D and 8E are plan views viewed from the Z direction of G1 and G2 portions (see FIGS. 8A to 8C) showing an illustrative shape of the underframe conductor layer 1412, when the underframe conductor layer 1412 has a rectangular pattern partially provided along the inside of the resin molded portion 4. The underframe conductor layer 1412 has a pattern partially provided along the inside of the resin molded portion 4 and connected to the conductor layer 141 inside the underframe conductor layer 1412 via a connector 1413. In other words, the conductor layer 141 has the connector 1413 that electrically connects with each other part of the underframe conductor layer 1412 and part of the pattern outside the underframe conductor layer 1412 among other patterns in the conductor layer 141.

As described above, in the image sensor package structured as illustrated in FIGS. 8A to 8E, the underframe conductor layer 1412 is deformed, and the prepreg layer 18 also has a slight dent at the portion indicated by the arrow 19. In this embodiment, the underframe conductor layer 1412 is provided as a pattern that is partially connected through the connector 1413 to the conductor layer 141 outside the underframe conductor layer 1412. Therefore, the underframe conductor layer 1412 may be deformed and cause cracks in the connector 1413, and it may be damaged and separated from the peripheral pattern. When the damage such as a crack and a disconnection occurs in the connector 1413, the underframe conductor layer 1412 is electrically structured as a dummy pattern, which does not electrically vary. In addition, the underframe conductor layer 1412 having a predetermined thickness can reduce the dent in the prepreg layer 18 in the lower layer.

In this embodiment, when the underframe conductor layer 1412 is separated from the peripheral pattern, the structure is the same as that of the first embodiment, and the underframe conductor layer 1412 has a dummy pattern, which does not electrically vary. As a result, the image sensor package does not become electrically defective and the printed circuit board 1 does not contain any cracks.

### First Comparative Example

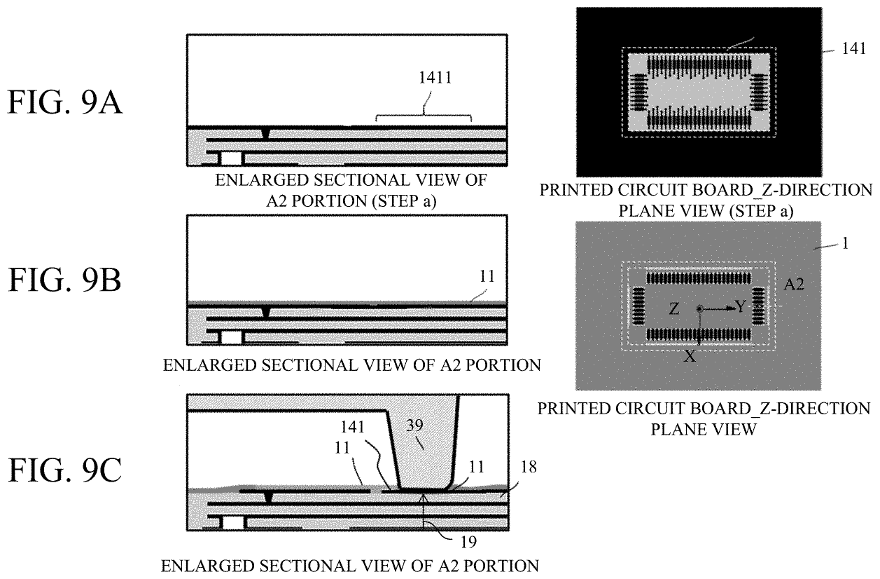

Referring now to FIGS. 9A to 9C, a description will be given of a first comparative example. FIGS. 9A to 9C illustrate a structure of an image sensor package according to this comparative example. FIG. 9A is an enlarged sectional view of an A2 portion in the step “a” and a printed circuit board_Z-direction plan view. FIG. 9B is an enlarged sectional view of the A2 portion and a printed circuit board_Z-direction plan view. FIG. 9C is an enlarged sectional view of the A2 portion.

FIG. 9A illustrates that the underframe conductor layer 1412 is electrically connected to the peripheral pattern on an entire circumference along the inside of the resin molded portion 4 in part where the underframe conductor layer 1412 is provided in the step b illustrated in FIG. 4B. FIG. 9B illustrates the step of forming the solder resist layer 11. FIG. 9C illustrates the printed circuit board 1 inserted into the same mold 3 as that of the first embodiment. A frame-shaped convex portion 39 is provided in the cavity in the mold 3. The frame-shaped convex portion 39 may enter the solder resist layer 11, and the solder resist layer 11 and the conductor layer 141 may be deformed. In that case, the prepreg layer 18 also has a slight dent at the portion indicated by the arrow 19.

As illustrated in FIGS. 9A to 9C, in this comparative example, since the stress applied from the frame-shaped convex portion 39 to the conductor layer 141 which is the closest conductor layer is applied to the printed circuit board 1, the prepreg layer 18 has a slight dent. Since the conductor layer 141 is provided on the entire surface of the portion opposite to the frame-shaped convex portion 39, it is impossible to control the positions of cracks that can occur in the conductor layer 141. Since the conductor layer 141 has a crack 142 and is partially disconnected, and its electric connection with the peripheral pattern becomes unstable. The electrical characteristic may change depending on the position of the crack 142 in the conductor layer.

### Second Comparative Example

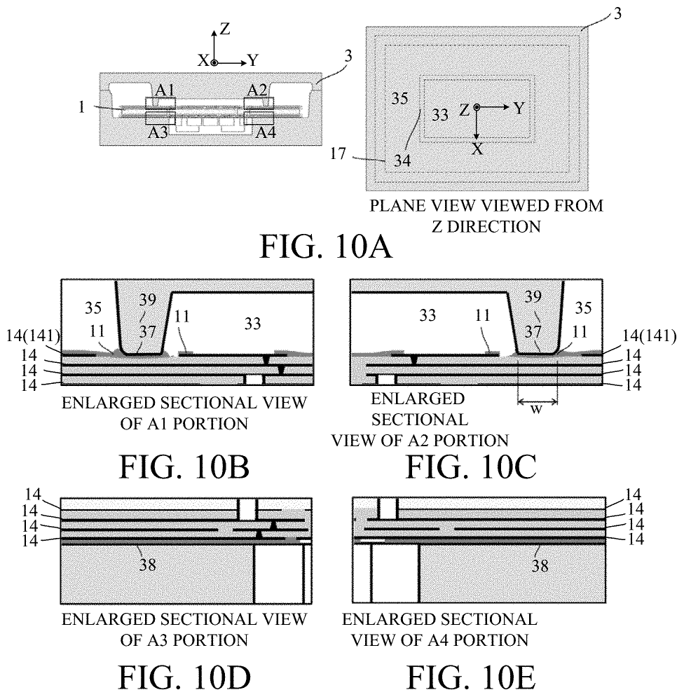

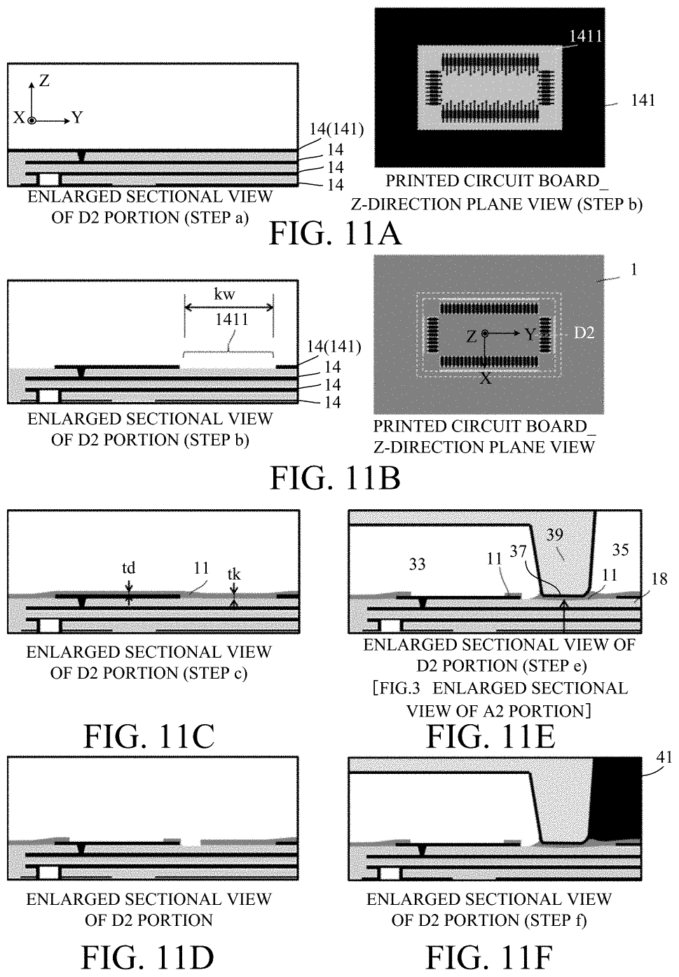

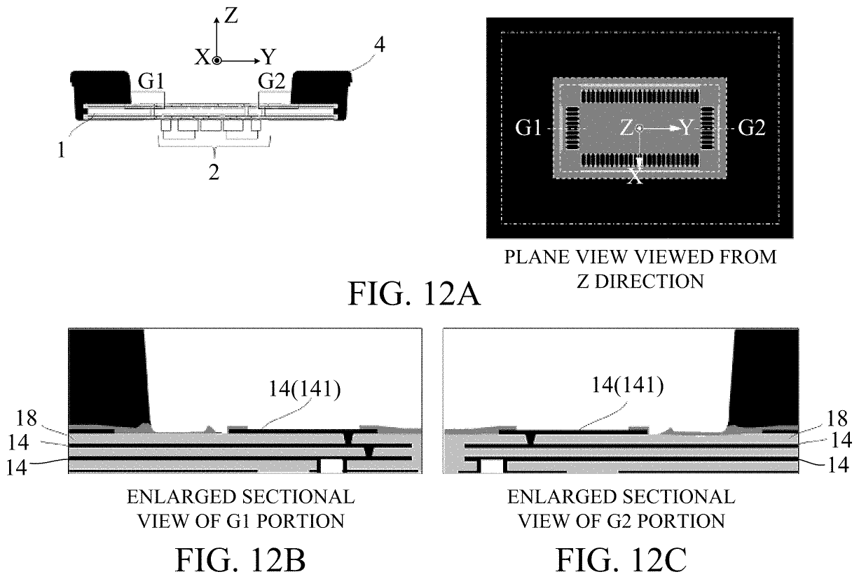

Referring now to FIGS. 10A to 10E, 11A to 11F, and 12A to 12C, a description will be given of a second comparative example. FIGS. 10A to 10E explain the printed circuit board 1 inserted into the mold 3 in this comparative example. FIGS. 11A to 11F and 12A to 12C illustrate a structure of the image sensor package according to this comparative example.

The printed circuit board_Z direction plan view (step b) in FIG. 11A is a plan view of the printed circuit board 1 from the Z direction. As illustrated in FIG. 11A, the conductor layer 141 has a frame-shaped opening 1411 in a portion sandwiched by two square-shaped broken lines. Similarly, the frame-shaped opening 1411 is illustrated in the enlarged sectional view of the D2 portion (step b) of FIG. 11B. As can be seen by comparing FIG. 11B with the enlarged sectional view of the A2 portion in FIG. 3C, the frame-shaped opening 1411 is a portion where the top frame-shaped plane 37 of the mold 3 and the conductor layer 141 are opposite to each other. The frame-shaped opening 1411 is provided in that portion, and a width kw of the frame-shaped opening 1411 is larger than a width w of the top frame-shaped plane 37.

FIGS. 12A to 12C illustrate the finished image sensor package (having no image sensor) according to this comparative example. The image sensor package includes a printed circuit board 1 having a plurality of conductor layers 14, and a resin molded portion 4 provided so as to surround the outer circumference of the printed circuit board 1. The conductor layer 141 among the plurality of conductor layers 14 which is the closest conductor layer closest to the resin molded portion 4 has the frame-shaped opening 1411 along the entire circumference inside the resin molded portion 4. At least part of the frame-shaped opening 1411 and the conductor layer 141 is covered with the solder resist layer 11 obtained by curing the liquid resist.

As illustrated in FIGS. 12A to 12C, in this comparative example, the frame-shaped opening 1411 is provided at the position pressed by the frame-shaped convex portion 39, and no conductor layer 141 is formed. Therefore, the damage such as a crack and a disconnection does not occur in the conductor layer 141, but the stress applied from the frame-shaped convex portion 39 is applied to the printed circuit board 1, and thus the prepreg layer 18 has a dent. In addition, the other conductor layer 141 may be disconnected, and the electrical characteristic may vary.

Each embodiment can provide an image sensor package that can form a resin molded portion on the outer circumference of the printed circuit board without causing an electric defect even if the printed circuit board gets damaged.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-018130, filed on Feb. 5, 2020 which is hereby incorporated by reference herein in its entirety.

What is claimed is:

1. An image sensor package comprising:
an image sensor;
a printed circuit board having a plurality of conductor layers; and
a resin molded portion provided so as to surround an outer circumference of the printed circuit board,
wherein a first conductor layer among the plurality of conductor layers, which is closest to the resin molded portion has a dummy pattern formed along a circumference inside the resin molded portion.

2. The image sensor package according to claim 1, wherein the dummy pattern is electrically connected to none of other patterns in the first conductor layer.

3. The image sensor package according to claim 1, wherein the first conductor layer includes a connector configured to electrically connect part of the dummy pattern and part of the other patterns to each other.

4. The image sensor package according to claim 3, wherein the connector electrically connects the dummy pattern and a pattern inside the dummy pattern among the other patterns to each other.

5. The image sensor package according to claim 3, wherein the connector electrically connects the dummy pattern and a pattern outside the dummy pattern among the other patterns to each other.

6. The image sensor package according to claim 1, wherein the dummy pattern is formed on an entire circumference inside the resin molded portion.

7. The image sensor package according to claim 1, wherein the dummy pattern is formed on part of the circumference inside the resin molded portion.

8. The image sensor package according to claim 1, further comprising a solder resist layer configured to cover at least part of the dummy pattern.
